(19) United States
(12) Patent Application Publication
(10) Pub. No.: US 2025/0359306 A1
(43) Pub. Date: Nov. 20, 2025

(54) SEMICONDUCTOR APPARATUSES

(71) Applicant: Samsung Electronics Co., Ltd., Suwon-si (KR)

(72) Inventors: Sangjine PARK, Suwon-si (KR); Youngjun KIM, Suwon-si (KR)

(73) Assignee: Samsung Electronics Co., Ltd., Suwon-si (KR)

(21) Appl. No.: 19/038,054

(22) Filed: Jan. 27, 2025

(30) Foreign Application Priority Data
May 16, 2024 (KR) 10-2024-0064051

(51) Int. Cl. H10D 84/83; H10D 62/40; H10D 62/60; H10D 62/832; H10D 64/66; H10D 84/01

(52) U.S. Cl. CPC H10D 84/832; H10D 62/60; H10D 84/013; H10D 84/0142; H10D 84/8311; H10D 84/8312; H10D 62/405; H10D 62/832; H10D 64/661

(57) ABSTRACT

A semiconductor apparatus may include a substrate including a first region and a second region; a first device on the first region; and a second device on the second region. The first device may include a channel structure including an insulating isolation pattern, first semiconductor patterns stacked under a lower surface of the insulating isolation pattern and including silicon germanium, and second semiconductor patterns stacked on an upper surface of the insulating isolation pattern and including silicon. The second device may include a semiconductor stack at a level corresponding to a level of the channel structure. The semiconductor stack may include an intermediate semiconductor layer, first lower semiconductor layers and second lower semiconductor layers alternately stacked under a lower surface of the intermediate semiconductor layer, and first upper semiconductor layers and second upper semiconductor layers alternately stacked on an upper surface of the intermediate semiconductor layer.

### CROSS-REFERENCE TO RELATED APPLICATION(S)

This application claims benefit of priority to Korean Patent Application No. 10-2024-0064051, filed on May 16, 2024 in the Korean Intellectual Property Office, the disclosure of which is incorporated herein by reference in its entirety.

### BACKGROUND

Example embodiments of the present disclosure relate to a semiconductor apparatus.

As demand for high performance, high speed, and/or multifunctionality of a semiconductor apparatus has increased, integration density of a semiconductor apparatus has increased. To overcome limitations in operating properties due to reduction of a size of a planar metal oxide semiconductor field effect transistor (MOSFET), there has been effort to develop a semiconductor apparatus including a gate-all-around type field effect transistor (FET) including nanosheets surrounded by a gate and a FinFET including a fin-shaped channel.

### SUMMARY

An example embodiment of the present disclosure provides a semiconductor apparatus having improved electrical properties and reliability.

According to an example embodiment of the present disclosure, a semiconductor apparatus may include a substrate including a first region and a second region; a semiconductor device on the first region of the substrate; and a semiconductor stack on the second region of the substrate. The semiconductor device may include a channel structure including an insulating isolation pattern, first semiconductor patterns under a lower surface of the insulating isolation pattern and being stacked and spaced apart from each other in a vertical direction, and second semiconductor patterns stacked and spaced apart from each other in the vertical direction on an upper surface of the insulating isolation pattern; first source/drain patterns on both sides in a first direction of the channel structure and connected to both sides of the first semiconductor patterns, respectively; second source/drain patterns on the both sides of the channel structure and connected to both sides of the second semiconductor patterns, respectively; a first gate structure extending in a second direction intersecting the first direction and surrounding the first semiconductor patterns; and a second gate structure extending in the second direction and surrounding the second semiconductor patterns. The semiconductor stack may include an intermediate semiconductor layer at a level corresponding to a level of the insulating isolation pattern; first lower semiconductor layers and second lower semiconductor layers alternately stacked under a lower surface of the intermediate semiconductor layer; and first upper semiconductor layers and second upper semiconductor layers alternately stacked on an upper surface of the intermediate semiconductor layer. The first semiconductor patterns and the second lower semiconductor layers may include a first semiconductor material, and the second semiconductor patterns and the second upper semiconductor layers may include a second semiconductor material. One of the first semiconductor material and the second semiconductor material may includes silicon and an other of the first semiconductor material and the second semiconductor material may include silicon germanium including germanium in a first concentration. The first lower semiconductor layers and the first upper semiconductor layers may include silicon germanium including germanium in a second concentration. The second concentration may be higher than the first concentration. The intermediate semiconductor layer may include silicon germanium in a third concentration, and the third concentration may be higher than the second concentration.

According to an example embodiment of the present disclosure, a semiconductor apparatus may include a substrate including a first region and a second region; a first device on the first region of the substrate; and a second device on the second region of the substrate. The first device may include a channel structure including an insulating isolation pattern, first semiconductor patterns under a lower surface of the insulating isolation pattern and being stacked and spaced apart from each other in a vertical direction, and second semiconductor patterns stacked and spaced apart from each other in the vertical direction on an upper surface of the insulating isolation pattern, the first semiconductor patterns and the second semiconductor patterns including silicon germanium and silicon, respectively; a pair of first source/drain patterns on both sides in a first direction of the channel structure and connected to both sides of the first semiconductor patterns, respectively; a pair of second source/drain patterns on the both sides of the channel structure and connected to both sides of the second semiconductor patterns, respectively; and a gate structure extending in a second direction, the second direction intersecting the first direction, the gate structure surrounding the first semiconductor patterns and the second semiconductor patterns. The second device may include a semiconductor stack at a level corresponding to a level of the channel structure. The semiconductor stack may include an intermediate semiconductor layer, first lower semiconductor layers and second lower semiconductor layers alternately stacked under a lower surface of the intermediate semiconductor layer, and first upper semiconductor layers and second upper semiconductor layers alternately stacked on an upper surface of the intermediate semiconductor layer. The intermediate semiconductor layer, the first lower semiconductor layers, the second lower semiconductor layers, and the first upper semiconductor layers may include silicon germanium. The second upper semiconductor layers may include silicon. The first semiconductor patterns and the second lower semiconductor layers may have a same concentration of germanium.

According to an example embodiment of the present disclosure, a semiconductor apparatus may include a substrate including a first region and a second region, the second region being peripheral to the first region; a semiconductor device on the first region of the substrate; and a semiconductor stack on the second region of the substrate. The semiconductor device may include an insulating isolation pattern, first semiconductor patterns under a lower surface of the insulating isolation pattern and stacked and spaced apart from each other in a vertical direction, and second semiconductor patterns stacked and spaced apart from each other in the vertical direction on an upper surface of the insulating isolation pattern, the first semiconductor patterns and the second semiconductor patterns including silicon germanium and silicon, respectively. The semiconductor stack may include an intermediate semiconductor layer at a level corresponding to a level of the insulating isolation pattern, first lower semiconductor layers and a second lower semiconductor layer alternately stacked under a lower surface of the intermediate semiconductor layer, and first upper semiconductor layers and second upper semiconductor layers alternately stacked on an upper surface of the intermediate semiconductor layer. The intermediate semiconductor layer, the first lower semiconductor layers, the second lower semiconductor layers, and the first upper semiconductor layers may include silicon germanium. The second upper semiconductor layers may include silicon. The first semiconductor patterns and the second lower semiconductor layers may include germanium in a first concentration. The first lower semiconductor layers and the first upper semiconductor layers may include germanium in a second concentration. The second concentration may be higher than the first concentration. The intermediate semiconductor layer may include germanium in a third concentration. The third concentration may be higher than the second concentration.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor apparatus according to example embodiments of the present disclosure;

FIGS. 2A, 2B and 2C are cross-sectional diagrams illustrating first region A of a semiconductor apparatus in FIG. 1 taken along lines I-I′, II1-II1′, and II2-II2′;

FIGS. 3A and 3B are cross-sectional diagrams illustrating second region B of a semiconductor apparatus in FIG. 1 taken along lines III1-III1′, and IV-IV′;

FIG. 4 is a cross-sectional diagram illustrating a circuit device employable in a semiconductor apparatus according to example embodiments of the present disclosure, viewed from side;

FIG. 5 is a plan diagram illustrating a semiconductor apparatus according to example embodiments of the present disclosure;

FIG. 6 is a cross-sectional diagram illustrating second region of a semiconductor apparatus in FIG. 5 taken along line III2-III2′;

FIG. 7 is a cross-sectional diagram illustrating a circuit device employable in a semiconductor apparatus according to example embodiments of the present disclosure, viewed from side;

FIG. 8 is a plan diagram illustrating a semiconductor apparatus according to example embodiments of the present disclosure;

FIG. 9 is a cross-sectional diagram illustrating a semiconductor apparatus taken along line V-V′ of FIG. 8;

FIGS. 10A to 10H are cross-sectional diagrams illustrating a portion of processes of a method of manufacturing a semiconductor apparatus according to example embodiments of the present disclosure; and

FIGS. 11A to 11G are cross-sectional diagrams illustrating the other portion processes of a method of manufacturing a semiconductor apparatus according to example embodiments of the present disclosure.

### DETAILED DESCRIPTION

Hereinafter, embodiments of the present disclosure will be described as follows with reference to the accompanying drawings.

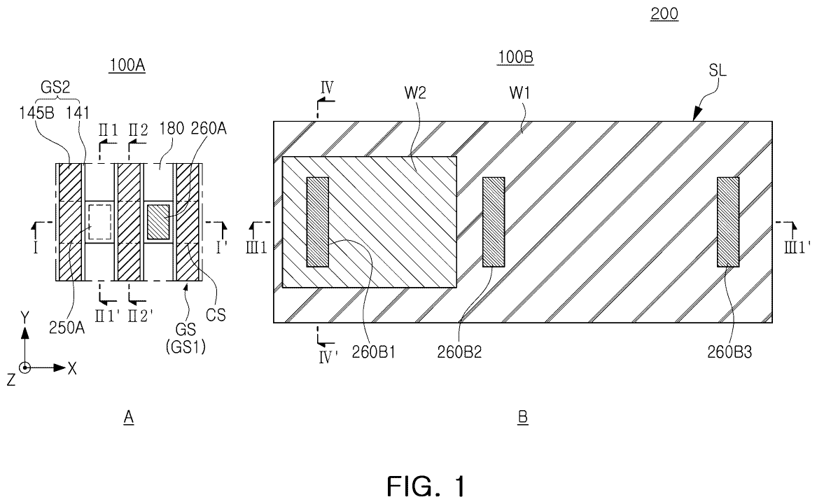

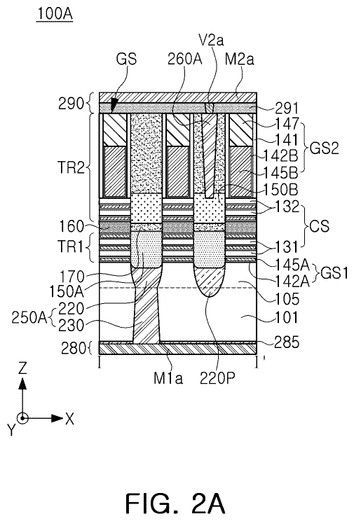

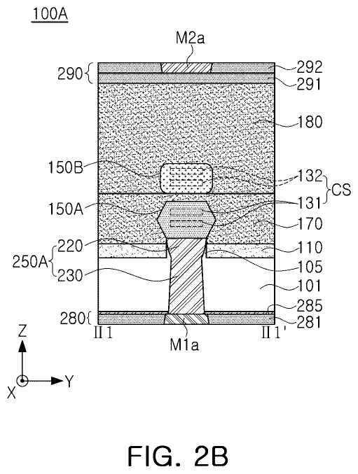

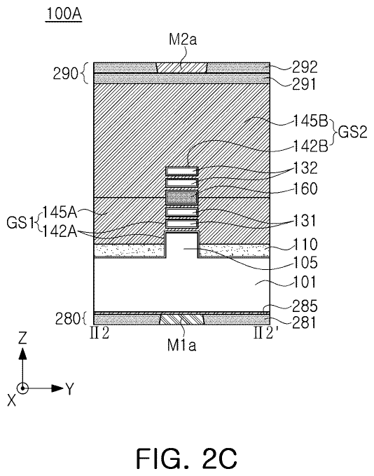

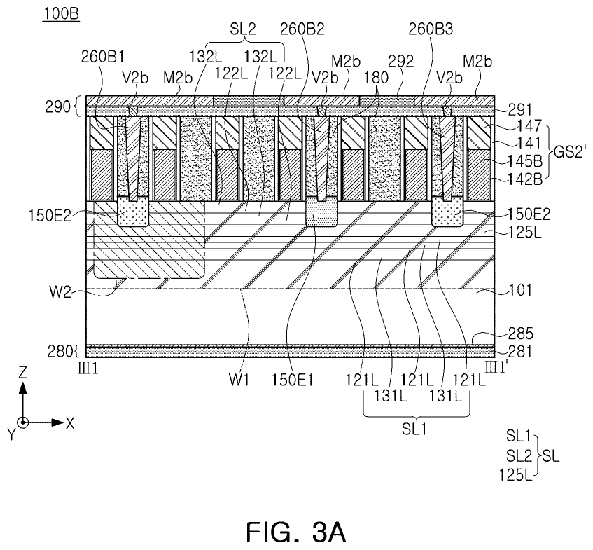

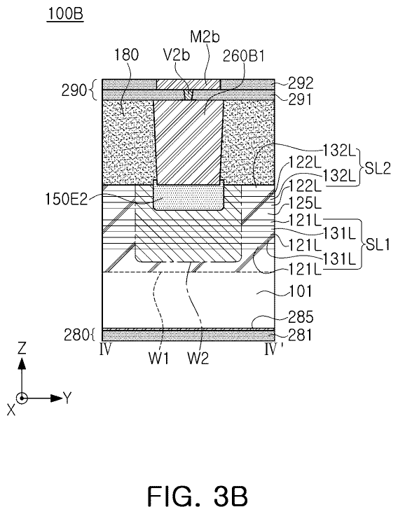

FIG. 1 is a plan diagram illustrating a semiconductor apparatus according to example embodiments. FIGS. 2A, 2B and 2C are cross-sectional diagrams illustrating first region A of a semiconductor apparatus in FIG. 1 taken along lines I-I′, II1-II1′, and II2-II2′. FIGS. 3A and 3B are cross-sectional diagrams illustrating second region B of a semiconductor apparatus in FIG. 1 taken along lines III1-III1′, and IV-IV′.

Referring to FIG. 1, a semiconductor apparatus 200 according to an example embodiment may include a substrate 101 including a first region A and a second region B arranged in a horizontal direction (e.g., X or Y-direction). In an example embodiment, a first device 100A (also referred to as “logic device”) may be disposed in the first region A of the substrate 101, and a second device 100B (also referred to as “circuit device”) may be disposed in the second region B of the substrate 101. The first device 100A may be referred to as a semiconductor device.

Referring to FIGS. 1 and 2A to 2C, the first device 100A of the semiconductor apparatus 200 according to an example embodiment may include a channel structure CS extending in the first direction (e.g., X-direction), and first and second gate structures GS1 and GS2 extending in the second direction (e.g., Y-direction) crossing one region of the channel structure CS and intersecting the first direction (e.g., X-direction). Here, the channel structure CS may be divided into a lower channel structure including a first semiconductor patterns 131 and an upper channel structure including a second semiconductor patterns 132.

The substrate 101 may include a semiconductor material, for example, a group IV semiconductor, a group III-V compound semiconductor, or a group II-VI compound semiconductor. For example, a group IV semiconductor may include silicon (Si), germanium (Ge), or silicon germanium (SiGe). The substrate 101 may include a bulk wafer, an epitaxial layer, or a silicon on insulator (SOI) layer. In some example embodiments, the substrate 101 may be an insulating substrate including an insulating material. For example, after a substrate is removed, which is a semiconductor, an insulating material layer may be formed in the removed region, thereby providing an insulating substrate. An insulating material included in the insulating substrate may include at least one of silicon oxide, silicon nitride, silicon oxynitride, silicon oxycarbide, and silicon oxycarbonitride.

As illustrated in FIG. 2A, the active pattern 105 may have a fin-type structure extending from the substrate 101 in the first direction (e.g., X-direction). As illustrated in FIGS. 2B to 2C, the device isolation layer 110 may define an active pattern 105 in the substrate 101. The device isolation layer 110 may be disposed on the substrate 101, and a portion of the active pattern 105 may protrude from an upper surface of the device isolation layer 110. The device isolation layer 110 may be formed, for example, by a shallow trench isolation (STI) process. The device isolation layer 110 may include an insulating material. For example, the device isolation layer 110 may include, for example, silicon oxide, silicon nitride, silicon oxynitride, or a combination thereof.

In an example embodiment, the active pattern 105 may be configured as a portion of the substrate 101, which is a semiconductor, as a semiconductor pattern, but an example embodiment thereof is not limited thereto. In some example embodiments, the active pattern 105 may be replaced with an insulating pattern including an insulating material. In the process of forming the insulating substrate described above, a portion or the entirety of the active pattern 105 may be removed and the space in which a portion or the entirety of the active pattern 105 is removed may be filled with an insulating material, such that the semiconductor apparatus 200 may have an insulating pattern corresponding to the active pattern 105. For example, the insulating material included in the insulating pattern may include at least one of silicon oxide, silicon nitride, silicon oxynitride, silicon oxycarbide, and silicon oxycarbonitride. In some example embodiments, the insulating pattern and/or the insulating substrate may include the same material as a material of the device isolation layer 110.

In an example embodiment, the first device 100A may include first and second transistors TR1 and TR2 stacked on the first region A of the substrate 101. The first transistor TR1 disposed in a lower portion may include a first semiconductor patterns 131, a first gate structure GS1 and a first source/drain patterns 150A, which may be a lower channel structure, and the second transistor TR2 disposed in an upper portion may include second semiconductor patterns 132, a second gate structure GS2 and second source/drain patterns 150B, which may be an upper channel structure. Each of the first and second transistors TR1 and TR2 may be a multi-bridge channel FET (MBCFET™).

The first transistor TR1 may be one of an N-type MOSFET and a P-type MOSFE, and the second transistor TR2 may be the other of a P-type MOSFET and an N-type MOSFET. In an example embodiment, the first transistor TR1 may be a P-type MOSFET, and the second transistor TR2 may be an N-type MOSFET.

Specifically, referring to FIG. 2A, the channel structure CS may include an insulating isolation pattern 160, first semiconductor patterns 131 stacked and spaced apart from each other in the third direction (e.g., Z-direction), a vertical direction, under a lower surface of the insulating isolation pattern 160, and second semiconductor patterns 132 stacked and spaced apart from each other in the third direction (e.g., Z-direction) on an upper surface of the insulating isolation pattern 160.

Among the first semiconductor patterns 131, the insulating isolation pattern 160 may be disposed on an uppermost first semiconductor pattern, and the second semiconductor patterns 132 may be stacked and spaced apart from each other on the insulating isolation pattern 160. The insulating isolation pattern 160 may be arranged to overlap the first semiconductor patterns 131 and the second semiconductor patterns 132 in the third direction (e.g., Z-direction), a vertical direction.

In some example embodiments, a plurality of the first semiconductor patterns 131 may be provided (e.g., two or three first semiconductor patterns). The first semiconductor patterns 131 may include silicon germanium (SiGe). A plurality of the second semiconductor patterns 132 may be provided (e.g., two or three second semiconductor patterns). For example, the second semiconductor patterns 132 may include silicon (Si). In some example embodiments, one of the first semiconductor patterns 131 and the second semiconductor patterns 132 may include silicon, and an other of the first semiconductor patterns 131 and the second semiconductor patterns 132 may include silicon germanium.

To improve carrier mobility (e.g., hole mobility), SiGe of the first semiconductor patterns 131 may include germanium in a first concentration. For example, the first concentration may range from 4 atom % to 7 atom %. Also, in terms of improving carrier mobility, an upper surface of the first semiconductor patterns 131 may be a (110) crystal plane. The first semiconductor pattern 131 may be grown, for example, on an upper surface of the silicon substrate, which is a (110) crystal plane. An upper surface of the second semiconductor patterns 132 may be a (110) crystal plane.

The insulating isolation pattern 160 may include an insulating material, and may include, for example, at least one of silicon nitride, silicon oxynitride, and silicon carbonitride. The insulating isolation pattern 160 may be a single insulating material layer, but in some example embodiments, the insulating isolation pattern 160 may include a plurality of insulating material layers.

The gate structure GS employed in an example embodiment may include a first gate structure GS1 and a second gate structure GS.

Referring to FIGS. 1, 2A and 2C, the first gate structure GS1 may cross one region of the active pattern 105 and may extend in the second direction (e.g., Y-direction), and similarly, the second gate structure GS2 may extend in the second direction (e.g., Y-direction).

Specifically, referring to FIGS. 2A and 2B, the first gate structure GS1 employed in an example embodiment may include a first gate electrode 145A surrounding the first semiconductor patterns 131, and a first gate insulating film 142A between the first semiconductor patterns 131 and the first gate electrode 145A. In some example embodiments, the first gate insulating film 142A may be formed between the first semiconductor patterns 131 and the first gate electrode 145A, and may also extend in the second direction (e.g., Y-direction) along a lower surface of the insulating isolation pattern 160.

Similarly, the second gate structure GS2 employed in an example embodiment may include a second gate electrode 145B surrounding the second semiconductor patterns 132, a second gate insulating film 142B between the second semiconductor patterns 132 and the second gate electrode 145B, gate spacers 141 disposed on both sidewalls of the second gate electrode 145B, and a gate capping layer 147 disposed on the second gate electrode 145B between the gate spacers 141.

The first and second gate electrodes 145A and 145B employed in an example embodiment may include different conductive materials. For example, the first and second gate electrodes 145A and 145B may include at least one of W, Ti, Ta, Mo, TiN, TaN, WN, TION, TiAlC, TiAlN, and TaAlC. In some example embodiments, the first and second gate electrodes 145A and 145B may include a semiconductor material, such as doped polysilicon. At least one of the first and second gate electrodes 145A and 145B may include a multilayer structure formed of different materials.

The first and second gate insulating films 142A and 142B may include a dielectric material. For example, each of the first and second gate insulating films 142A and 142B may include at least one of oxide, nitride, and high-K material. The high-K material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). The first and second gate insulating films 142A and 142B may include the same dielectric material or may include different dielectric materials.

The gate spacers 141 may include the same insulating material or partially different insulating materials. For example, the gate spacers 141 may include at least one of silicon oxide, silicon nitride, and silicon oxynitride. In some example embodiments, the gate spacer 141 may include a multilayer structure including different materials. The gate capping layer 147 may include, for example, silicon nitride, silicon oxynitride, silicon carbonitride, or silicon oxycarbonitride.

The first device 100A according to an example embodiment may further include a pair of first source/drain patterns 150A disposed on both sides in the first direction (e.g., X-direction) of the first semiconductor patterns 131, and a pair of second source/drain patterns 150B disposed on both sides in the first direction (e.g., X-direction) of the second semiconductor patterns 132. The first and second source/drain patterns 150A and 150B may be arranged to overlap each other in the third direction (e.g., Z-direction) which is a vertical direction.

The first source/drain patterns 150A may include an epitaxial layer grown from both side surfaces of the first semiconductor patterns 131. Similarly, the second source/drain patterns 150B may include an epitaxial layer grown from both side surfaces of the second semiconductor patterns 132.

The first and second source/drain patterns 150A and 150B may include impurities of different types and/or having different concentrations. In some example embodiments, the first source/drain patterns 150A may include an epitaxial layer doped with first conductivity-type impurities, and the second source/drain patterns 150B may include an epitaxial layer doped with second conductivity-type impurities.

When the first transistor TR1 is provided as a P-MOSFET, the first source/drain patterns 150A may include silicon germanium (SiGe) doped with P-type impurities. When the second transistor TR2 is provided as an N-MOSFET, the second source/drain patterns 150B may include silicon or silicon germanium (SiGe) doped with N-type impurities.

In some example embodiments, cross sections in the second direction (e.g., Y-direction) of the first and second source/drain patterns 150A and 150B may have different shapes. For example, the cross section of the first source/drain patterns 150A may have a pentagonal shape, and the cross section of the second source/drain patterns 150B may have a polygonal shape having gentle edges (see FIG. 2B).

The first device 100A according to an example embodiment may include an isolating insulation layer 170 disposed on the device isolation layer 110 and covering the first source/drain patterns 150A. As illustrated in FIG. 2B, the isolating insulation layer 170 may be disposed on the first source/drain patterns 150A and may electrically isolate the first source/drain patterns 150A and the second source/drain patterns 150B from each other. The first device 100A according to an example embodiment may include an interlayer insulating layer 180 covering the second source/drain patterns 150B and disposed on the isolating insulation layer 170.

The isolating insulation layer 170 and the interlayer insulating layer 180 may be silicon oxide. For example, the isolating insulation layer 170 and the interlayer insulating layer 180 may include spin-on hardmask (SOH), flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide or combinations thereof. The isolating insulation layer 170 and the interlayer insulating layer 180 may be formed using chemical vapor deposition (CVD) process, a flowable-CVD process, or a spin coating process.

The first device 100A according to an example embodiment may further include a first lower contact 250A connected to the first source/drain pattern 150A and a first upper contact 260A connected to the second source/drain pattern 150B. The first lower contact 250A may penetrate the substrate 101 and may be connected to the first source/drain pattern 150A. The first lower contact 250A employed in an example embodiment may include a conductive via 230 penetrating the substrate 101 and a conductive connection portion 220 formed by selectively removing the buried sacrificial pattern 220P. The buried sacrificial pattern 220P may remain in a lower portion of first source/drain pattern 150A in which the first lower contact 250A is not formed. The first device 100A may further include gate contacts (not illustrated) connected to the first and/or second gate electrodes 145A and/or 145B. For example, the first lower and upper contacts 250A and 260A may include at least one of titanium nitride (TiN), tantalum nitride (TaN), tungsten nitride (WN), tungsten carbon nitride (WCN), titanium (Ti), tantalum (Ta), tungsten (W), copper (Cu), aluminum (Al), cobalt (Co), ruthenium (Ru) and molybdenum (Mo).

Referring to FIG. 1, a semiconductor apparatus 200 according to an example embodiment may include the second device 100B included in a peripheral circuit in the second region B. The second region B may be a peripheral region of the semiconductor apparatus 200, but an example embodiment thereof is not limited thereto, and the second device 100B may be disposed in a main region together with the first device 100A.

Referring to FIGS. 3A and 3B, the second device 100B employed in an example embodiment may include a semiconductor stack SL in which semiconductor layers 121L, 122L, 125L, 131L, and 132L having different compositions are stacked.

The semiconductor stack SL may be provided as a body structure of the second device 100B to configure passive devices (e.g., resistors, capacitors, or the like) or active devices (e.g., PN diodes, bipolar junction transistors (BJT), or the like) required for circuit configuration. In some example embodiments, the semiconductor stack SL may include at least one of a first conductivity-type impurity region W1 and a second conductivity-type impurity region W2. In an example embodiment, the semiconductor stack SL may include a first conductivity-type impurity region W1 and a second conductivity-type impurity region W2 surrounding the first conductivity-type impurity region W1.

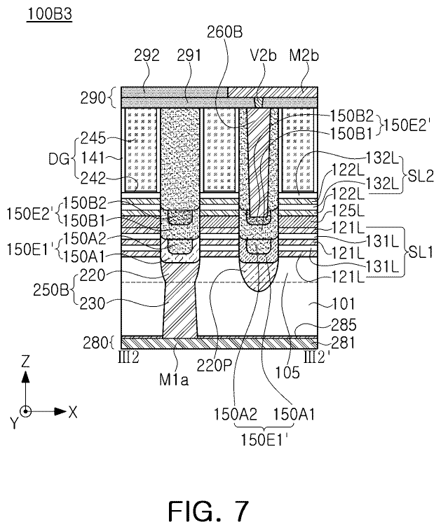

The second device 100B according to an example embodiment may further include a plurality of gate structures GS2′ extending on the semiconductor stack SL in the second direction (Y-direction). The gate structure GS2′ employed in an example embodiment may have a structure corresponding to the second gate structure GS2, but may be understood as a dummy structure not involved in driving. The gate structure GS2′ employed in an example embodiment may include a second gate electrode 145B extending in the second direction (e.g., Y-direction) on an upper surface of the semiconductor stack SL, a second gate insulating film 142B between an upper surface of the semiconductor stack SL and the second gate electrode 145B, gate spacers 141 disposed on both sidewalls of the second gate electrode 145B, and a gate capping layer 147 disposed on the second gate electrode 145B between the gate spacers 141. In some example embodiments (see FIG. 7), the gate structure GS2′ of second device 100B may remain as a dummy gate structure or inactive gate structure.

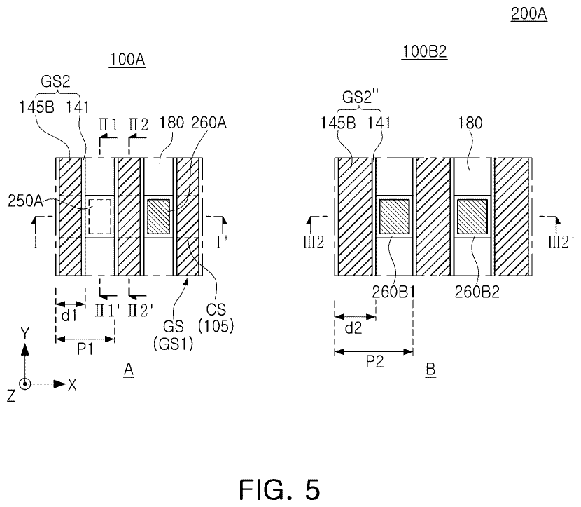

In an example embodiment, the plurality of gate structures GS2′ may be arranged with the same pitch and/or the same width as those of the second gate structures GS2 of the first device 100A. However, in some example embodiments (FIGS. 5 to 7), the plurality of gate structures GS2′ may be arranged with a width and/or a pitch greater than those of the second gate structures GS2 of the first device 100A.

Referring to FIGS. 3A and 3B, the semiconductor stack SL employed in an example embodiment may include an intermediate semiconductor layer 125L, a lower stack SL1 including first lower semiconductor layers 121L and second lower semiconductor layers 131L alternately stacked under a lower surface of the intermediate semiconductor layer 125L, and an upper stack SL2 including first upper semiconductor layers 122L and second upper semiconductor layers 132L alternately stacked on an upper surface of the intermediate semiconductor layer 125L.

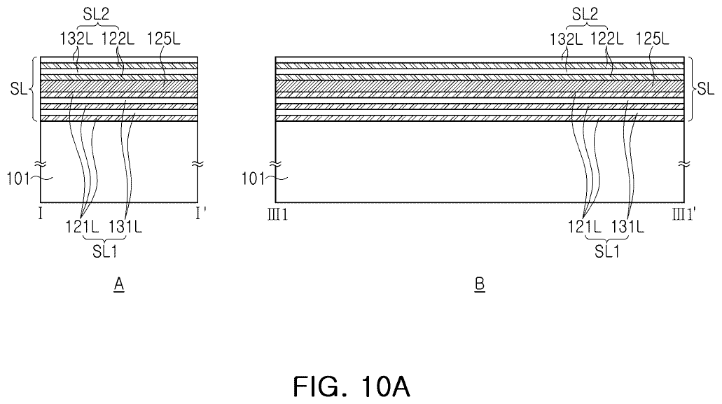

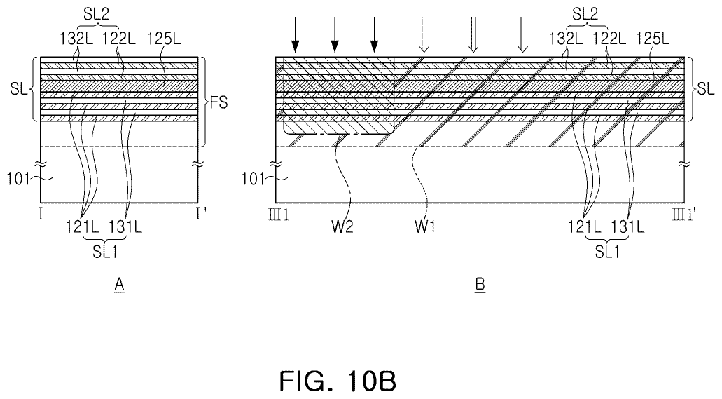

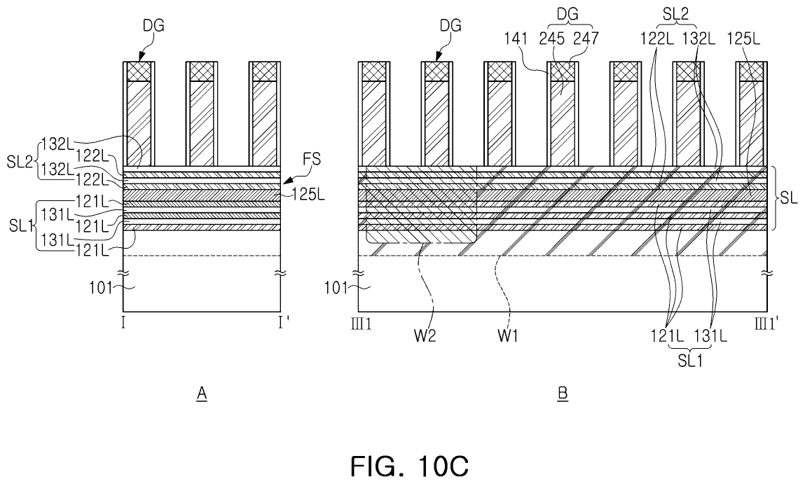

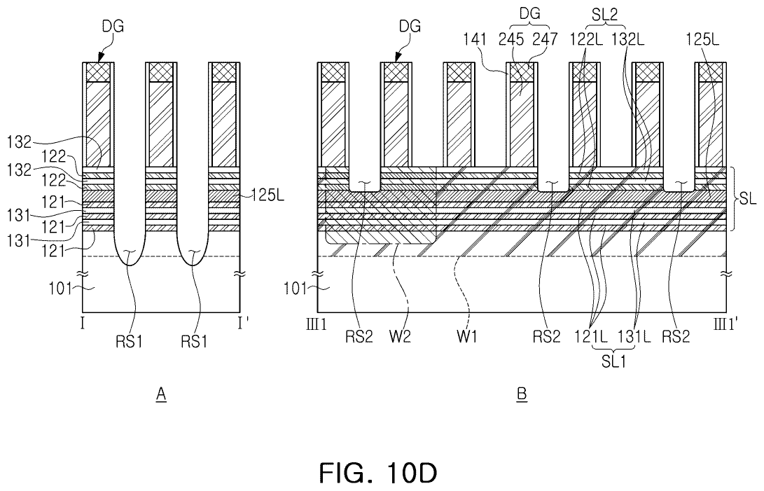

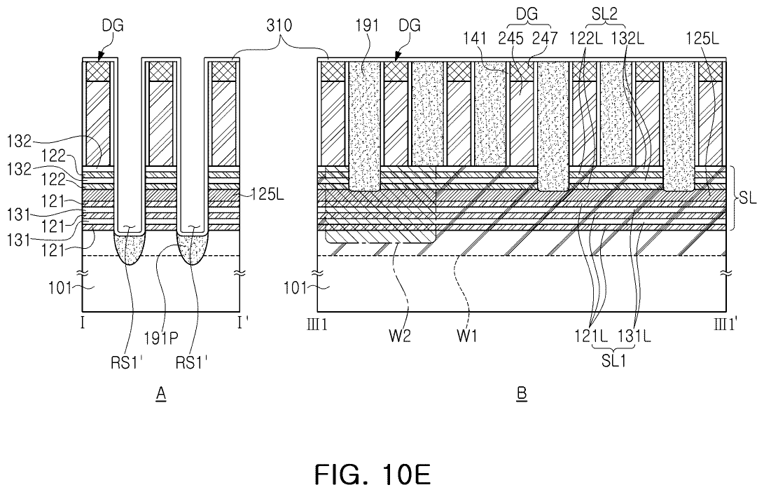

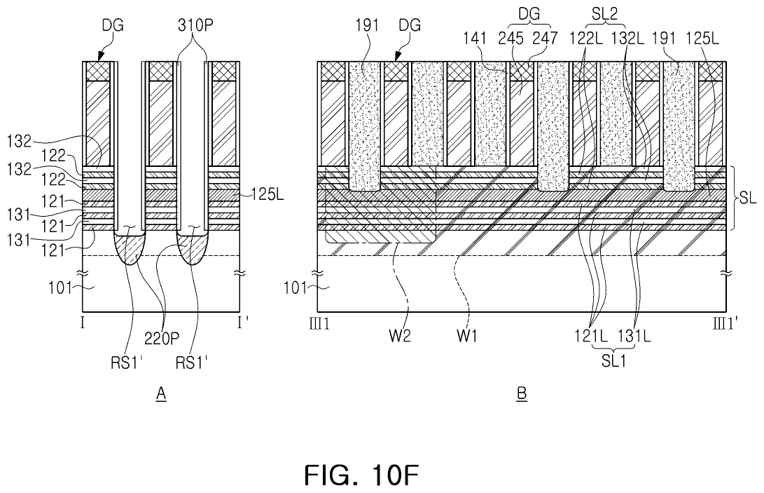

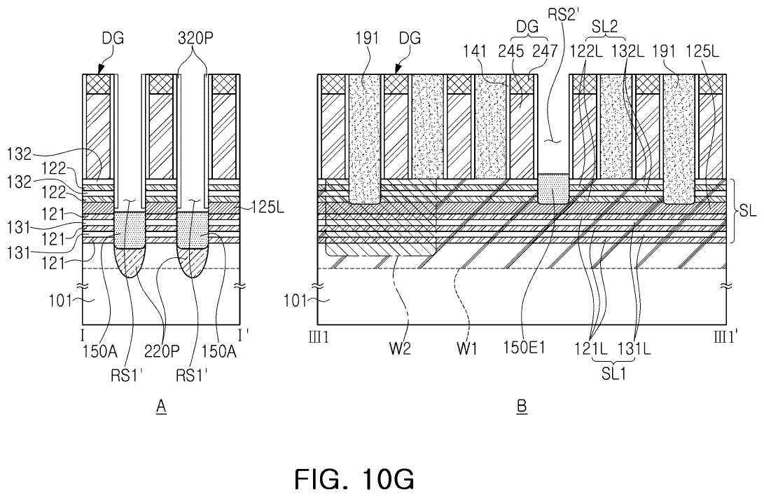

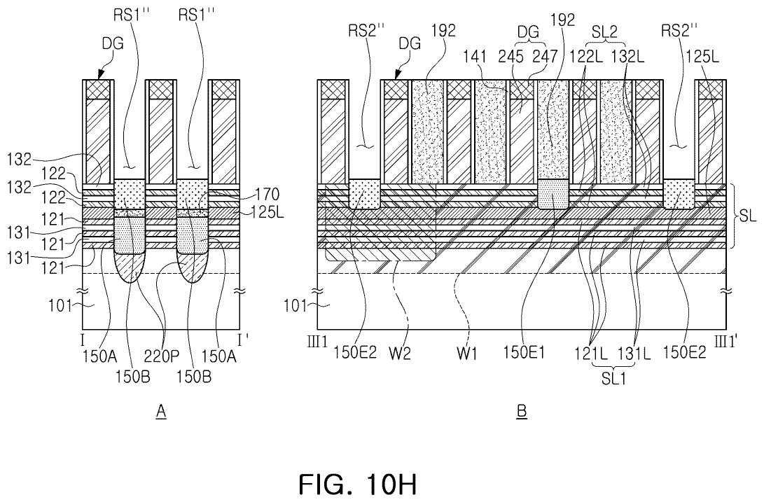

The semiconductor stack SL of the second device 100B may be understood as a structure corresponding to the semiconductor stack (SL in FIG. 10A) forming the channel structure CS of the first device 100A.

Specifically, the intermediate semiconductor layer 125L may be disposed on a level corresponding to a level of the insulating isolation pattern 160 of the first device 100A. Similarly, the second lower and upper semiconductor layers 131L and 132L may be disposed on levels corresponding to levels of the first and second semiconductor patterns 131 and 132, respectively.

The second lower semiconductor layers 131L may correspond to the first semiconductor patterns 131 included in a lower channel structure of the first device 100A, respectively. Each of the second lower semiconductor layers 131L may include substantially the same material layer as a material layer of the first semiconductor patterns 131 and may have substantially the same thickness as the first semiconductor patterns 131. Similarly, the second upper semiconductor layers 132L may correspond to the second semiconductor patterns 132 included in the upper channel structure of the first device 100A, respectively. Each of the second upper semiconductor layers 132L may include substantially the same material layer as a material layer of the second semiconductor patterns 132 and may have substantially the same thickness as the second semiconductor patterns 132. The notion that elements are “substantially the same” may indicate that the elements may be completely the same and may also indicate that the elements may be determined to be the same in consideration of errors or deviations occurring during a process.

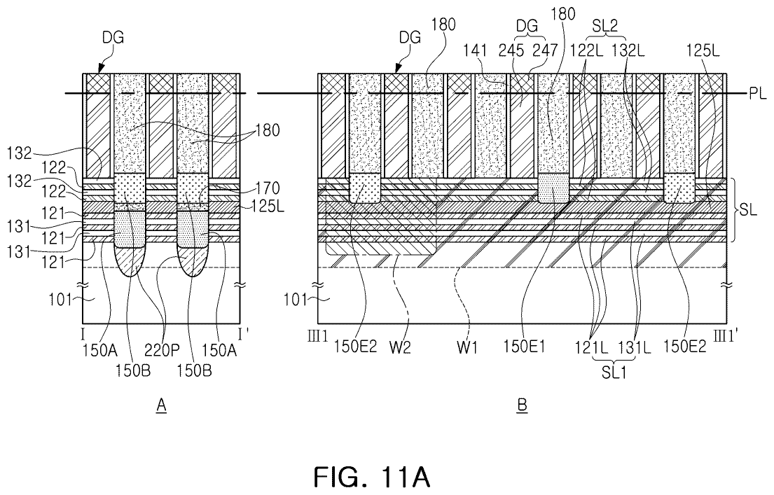

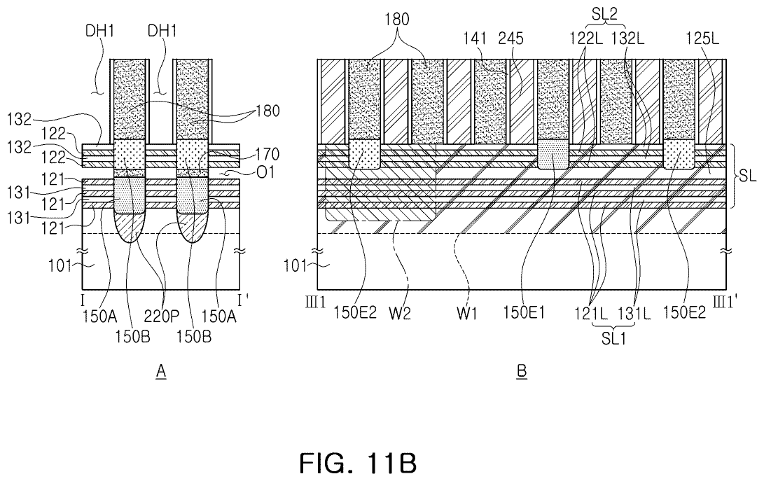

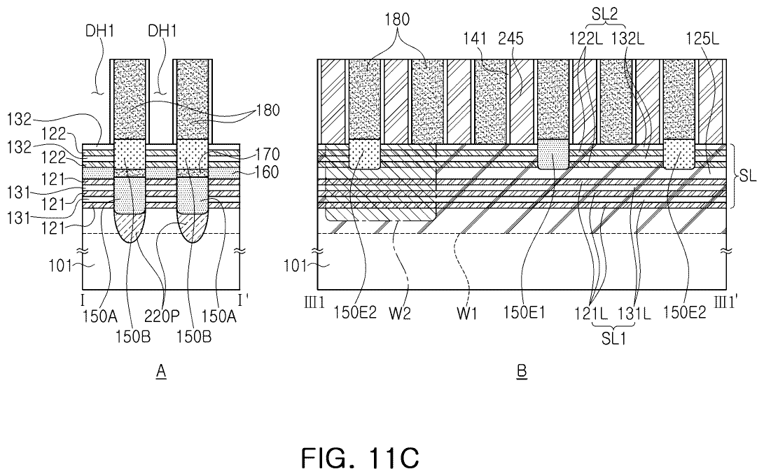

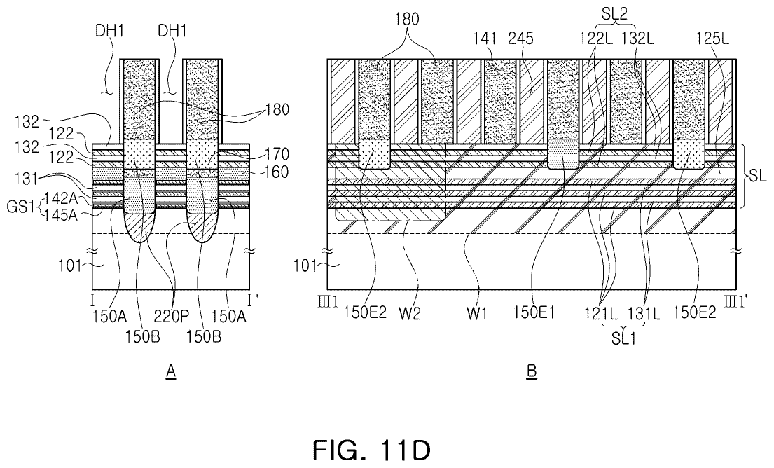

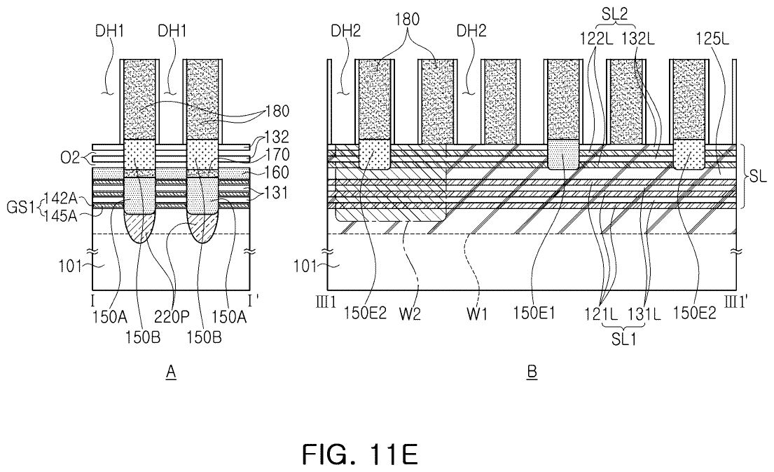

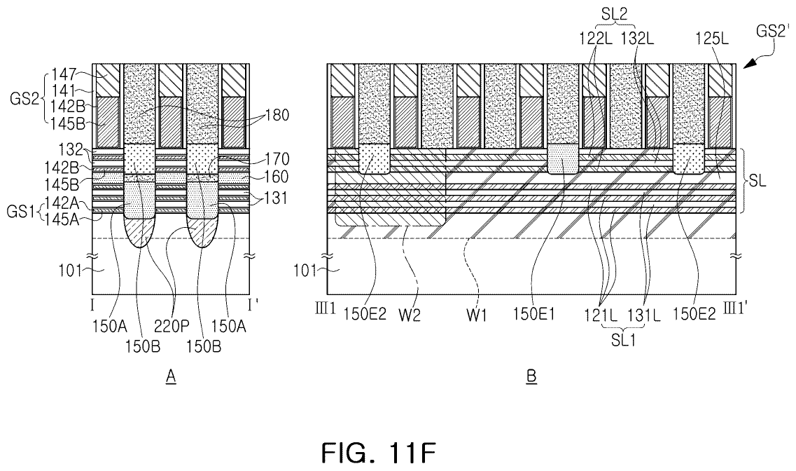

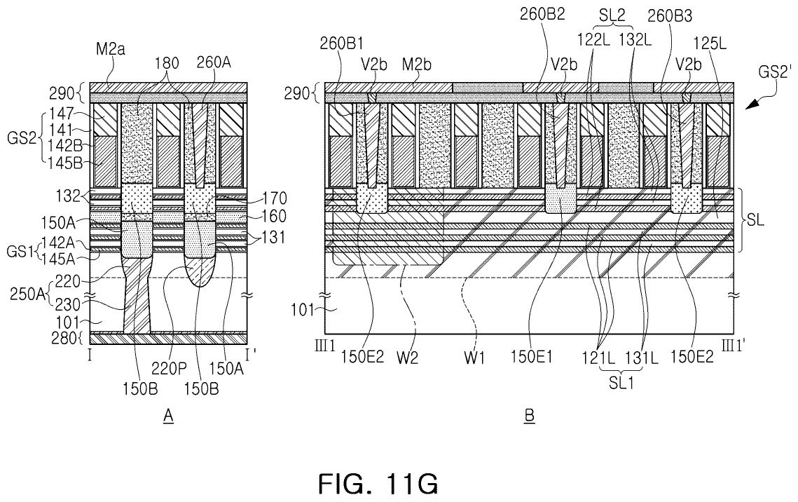

The first lower semiconductor layers 121L and the first upper semiconductor layers 122L may correspond to the first and second sacrificial patterns (121 and 122 in FIGS. 11A and 11B) to form the lower and upper channel structures of the first device 100A, respectively. Also, the intermediate semiconductor layer 125L may correspond to intermediate sacrificial patterns (125 in FIGS. 11A and 11B) to form the insulating isolation pattern 160 between the lower and upper channel structures of the first device 100A.

In an example embodiment, the semiconductor layers 121L, 122L, 125L, 131L, and 132L having different compositions may have different concentrations of germanium. The second lower semiconductor layers 131L may include silicon germanium substantially the same as that of the first semiconductor patterns 131, and the second upper semiconductor layers 132L may include a semiconductor substantially the same as that of the second semiconductor patterns 132, that is, silicon. As described above, the second lower semiconductor layers 131L may include germanium in a first concentration substantially similar to that of the first semiconductor patterns 131. For example, the second lower semiconductor layers 131L may include a concentration of germanium ranging from 4 atom % to 7 atom %.

Each of the first lower semiconductor layers 121L and the first upper semiconductor layers 122L may include silicon germanium having germanium of a second concentration rather than the first concentration. For example, the second concentration may range from 10 atom % to 20 atom %. In an example embodiment, the first lower semiconductor layers 121L may have a concentration of germanium greater than a concentration of germanium of each of the first upper semiconductor layers 122L, but an example embodiment thereof is not limited thereto, and the first lower semiconductor layers 121L and the first upper semiconductor layers 122L may have the same concentration of germanium.

The intermediate semiconductor layer 125L may include silicon germanium having germanium of a third concentration rather than the second concentration of each of the first lower semiconductor layers 121L and the first upper semiconductor layers 122L. For example, third concentration may range from 30 atom % to 45 atom %.

During the manufacturing process, in the semiconductor stack SL, some elements (e.g., Ge) may diffuse to other semiconductor layers adjacent thereto, and accordingly, in the final structure, concentrations of some elements may change slightly in each of the semiconductor layers 121L, 122L, 125L, 131L, and 132L. For example, the second lower semiconductor layers 131L may include substantially the same concentration of germanium as that of the first semiconductor patterns 131, and the concentration of germanium at the center in the thickness direction of the second lower semiconductor layers 131L may be close to the concentration of germanium of the first semiconductor patterns 131. Similarly, the second upper semiconductor layers 132L may include substantially the same silicon as that of the second semiconductor patterns 132, but a relatively lower concentration of germanium distribution may appear in the region adjacent to other semiconductor layers 122L and 125L in the second upper semiconductor layers 132L.

In some example embodiments, the thickness of the intermediate semiconductor layer 125L may be greater than the thickness of each of the first and second lower semiconductor layers 121L and 131L or the first and second upper semiconductor layers 122L and 132L.

The semiconductor stack SL may have a recess in a portion of the regions between the plurality of gate structures, and a first conductivity-type epitaxial pattern 150E1 and two second conductivity-type epitaxial patterns 150E2 and 150E2 may be formed in the recesses, respectively.

As described above, the semiconductor stack SL may include a first conductivity-type impurity region W1 and a second conductivity-type impurity region W2 surrounding the first conductivity-type impurity region W1. The first conductivity-type impurity region W1 may be an N-type impurity region, and the second conductivity-type impurity region W2 may be a P-type impurity region. In an example embodiment, the first conductivity-type epitaxial pattern 150E1 may be a P-type epitaxial layer, similar to first source/drain patterns 150A, and the second conductivity-type epitaxial patterns 150E2, similar to second source/drain patterns 150B, may be an N-type epitaxial layer.

Through the arrangement described above, as illustrated in FIGS. 3A and 3B, in the second device 100B according to an example embodiment, the second conductivity-type epitaxial patterns 150E2 may be an emitter and a collector of an NPN bipolar transistor, respectively, and the first conductivity-type epitaxial pattern 150E1 may be a base of the NPN bipolar transistor.

In an example embodiment, the first conductivity-type epitaxial pattern 150E1 and the second conductivity-type epitaxial patterns 150E2 may be epitaxial layers grown in the same process as a process of forming the first source/drain patterns 150A and the second source/drain patterns 150B of the first device 100A, respectively

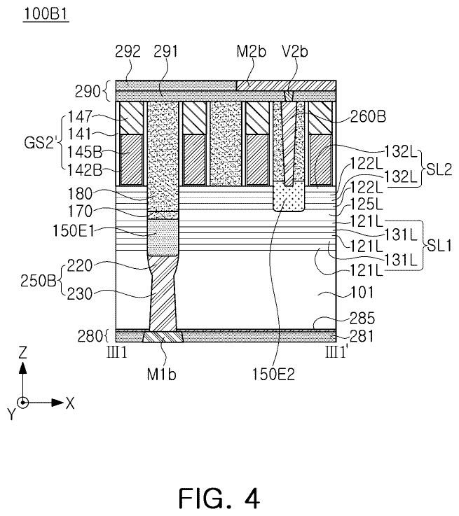

In an example embodiment, the recess of the semiconductor stack SL in which the first and second conductivity-type epitaxial patterns 150E1 and 150E2 are formed may have a depth lower than that of the recess of the first device 100A (see FIG. 10D), but an example embodiment thereof is not limited thereto, and at least one of the recesses of the semiconductor stack SL may be formed to have the same depth as that of the recess of the first device 100A. Also, in an example embodiment, the recesses for the first and second conductivity-type epitaxial patterns 150E1 and 150E2 may have the same depth, but an example embodiment thereof is not limited thereto, and the recesses may have different depths. For example, the recess for the first conductivity-type epitaxial pattern 150E1 may have a depth different from the depth of the recesses for the second conductivity-type epitaxial pattern 150E2 (see FIG. 4).

Similar to the first upper contact 260A of the first device 100A, the second device 100B according to an example embodiment may further include a plurality of second upper contacts 260B1, 260B2, and 260B3 penetrating the interlayer insulating layer 180 and connected to the first and second conductivity-type epitaxial pattern 150E1 and 150E2. The plurality of second upper contacts 260B1, 260B2, and 260B3 may be used as an emitter electrode, a base electrode and a collector electrode. For example, the second upper contacts 260B1, 260B2, and 260B3 may include at least one of titanium nitride (TiN), tantalum nitride (TaN), tungsten nitride (WN), tungsten carbon nitride (WCN), titanium (Ti), tantalum (Ta), tungsten (W), copper (Cu), aluminum (Al), cobalt (Co), ruthenium (Ru) and molybdenum (Mo).

The semiconductor apparatus 200 according to an example embodiment may include a first interconnection structure 280 (also referred to as a “rear interconnection structure”) disposed under a lower surface of the substrate 101, and a second interconnection structure 290 disposed on the interlayer insulating layer 180 (also referred to as “front interconnection structure”). The first interconnection structure 280 and second interconnection structure 290 may be configured to electrically connect first devices 100A to second devices 100B across the first and second regions A and B.

The first interconnection structure 280 may include the first interconnection insulating layer 281 disposed under a lower surface of the substrate 101 and a first interconnection line M1a disposed in the first interconnection insulating layer 281. In the first region A, the first interconnection line M1a may be connected to the first lower contact 250A of the first device 100A (see FIG. 2A). The first interconnection line M1a may be a power supply line. In an example embodiment, an etching stop film 285 may be disposed between the substrate 101 and the first interconnection insulating layer 281. The etching stop film 285 may be used in the process of forming the first interconnection line M1a.

Similarly, the second interconnection structure 290 may include a second interconnection insulating layer 291 and 292 disposed on the interlayer insulating layer 180 and second interconnection lines M2a and M2b disposed in the second interconnection insulating layer 292. In the first region A, the second interconnection line M2a may be connected to the first upper contact 260A of the first device 100A through the metal via V2a (see FIG. 2A), and in second region B, the second interconnection lines M2b may be connected to the second upper contacts 260B1, 260B2, and 260B3 of the second device 100B through the metal vias V2b, respectively (see FIG. 3A).

For example, the first and second interconnection insulating layers 281, 291, and 292 may include silicon oxide, silicon oxynitride, SiOC, SiCOH, or a combination thereof. For example, the interconnection lines M1a, M2a, M2b and the metal vias V2a, V2b may include copper or copper-containing alloys. In some example embodiments, the interconnection lines M2a and M2b may be formed together with respective metal vias V2a and V2b using dual-damascene processes.

In an example embodiment, the first transistor TR1 may be implemented as a P-type MOSFET, and the second transistor TR2 may be implemented as an N-type MOSFET, but conversely, in some example embodiments, the first transistor TR1 may be implemented as an N-type MOSFET, and the second transistor TR2 may be implemented as a P-type MOSFET. For example, the second lower semiconductor layers 131L may include silicon substantially the same as that of the first semiconductor patterns 131, and the second upper semiconductor layers 132L may include silicon germanium substantially the same as that of the second semiconductor patterns 132. Here, the second upper semiconductor layers 132L may include germanium in a first concentration substantially similar to that of the second semiconductor patterns 132. For example, the first concentration may include a concentration of germanium ranging from 4 atom % to 7 atom %. Also, the first source/drain patterns 150A may include silicon, and second source/drain patterns 150B may include silicon germanium.

FIG. 4 is a cross-sectional diagram illustrating a circuit device employable in a semiconductor apparatus according to example embodiments, viewed from side.

Referring to FIG. 4, a second device 100B1 according to an example embodiment may replace the second device 100B in the semiconductor apparatus 200 in FIG. 1 or may be employed together with the second device 100B, and unless otherwise indicated, the detailed description of the second device 100B1 according to an example embodiment may be combined with the description of the second device 100B illustrated in FIGS. 3A and 3B.

Similar to the semiconductor stack SL of the second device 100B in the aforementioned example embodiment, the second device 100B1 according to an example embodiment may include a semiconductor stack SL in which semiconductor layers 121L, 122L, 125L, 131L, and 132L having different compositions are disposed, and a plurality of gate structures GS2′ extending to the semiconductor stack SL. However, differently from the second device 100B in the aforementioned example embodiment, the second device 100B1 according to an example embodiment may be implemented as a PN diode or a P-i-N diode.

The semiconductor stack SL may include, for example, regions doped with low concentration N-type impurities or may include regions not intentionally doped.

In an example embodiment, a recess for the first conductivity-type epitaxial pattern 150E1 may be formed to have a depth greater than a depth of recesses for the second conductivity-type epitaxial pattern 150E2. The recess for the first conductivity-type epitaxial pattern 150E1 may be formed to have the same depth as the depth of the recess (RS1 in FIG. 10D) for the first and second source/drain patterns 150A and 150B of the first device 100A. The first conductivity-type epitaxial pattern 150E1 may be a P-type epitaxial layer similar to the first source/drain pattern 150A, and the second conductivity-type epitaxial pattern 150E2 may be an N-type epitaxial layer similar to the second source/drain pattern 150B.

Similarly to the first lower contact 250A of the first device 100A according to the aforementioned example embodiment, the second lower contact 250B may penetrate the substrate 101 and may be connected to the first conductivity-type epitaxial pattern 150E1. The second lower contact 250B employed in an example embodiment may include a conductive via 230 penetrating the substrate 101 and a conductive connection portion 220 formed by selectively removing the buried sacrificial pattern. The second lower contact 250B may be formed together in the process of forming the first lower contact 250A.

The second lower contact 250B and the second upper contact 260B may be connected to the first conductivity-type epitaxial pattern 150E1 and the second conductivity-type epitaxial patterns 150E2, respectively, and may be electrically connected to the first and second interconnection structures 280 and 290. Accordingly, the second device 100B1 according to an example embodiment implemented with a PN diode may form a circuit of the semiconductor apparatus 200 together with the first device 100A.

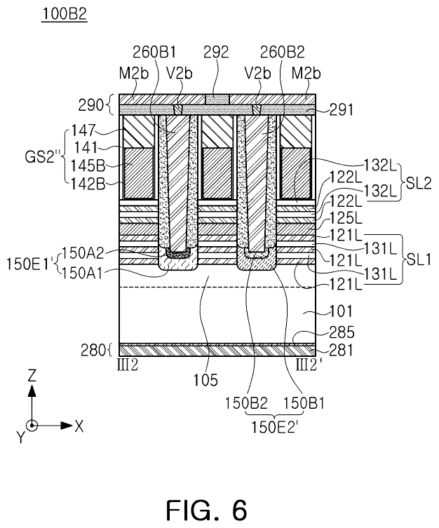

FIG. 5 is a plan diagram illustrating a semiconductor apparatus according to example embodiments. FIG. 6 is a cross-sectional diagram illustrating second region of a semiconductor apparatus in FIG. 5 taken along line III2-III2′.

Referring to FIGS. 5 and 6, the semiconductor apparatus 200A according to an example embodiment may be similar to the semiconductor apparatus 200 illustrated in FIGS. 1 to 3B other than the configuration in which the second device 100B2 has a gate structure GS2″ with a pitch P2 and a width d2 respectively larger than a pitch P1 and a width d1 of the gate structure GS of the first device 100A, and the configuration in which epitaxial patterns 150E1′ and 150E2′ and contact structures of a second device 100B2 are changed. Also, the components in an example embodiment may be understood by referring to the description of the same or similar components of the second device 100B illustrated in FIGS. 3A and 3B, unless otherwise indicated.

Similarly to the semiconductor stack SL of the second device 100B in the aforementioned example embodiment, the second device 100B2 according to an example embodiment may include a semiconductor stack SL in which semiconductor layers 121L, 122L, 125L, 131L, and 132L having different compositions are disposed. In an example embodiment, the semiconductor stack SL may include regions doped with low concentration N-type impurities, for example, or may include regions not intentionally doped.

Also, the gate structure GS2″ of the second device 100B2 may be arranged to have a pitch P2 and a width d2 respectively larger than a pitch P1 and a width d1 of the gate structure GS of the first device 100A. The recess of the second device 100B2 may also have a width relatively larger than that of the recess of the first device 100A. A first conductivity-type epitaxial pattern 150E1′ may be disposed in the left recess, and a second conductivity-type epitaxial pattern 150E2′ may be disposed in the right recess. The first conductivity-type epitaxial pattern 150E1′ may be formed together in the process of forming the first source/drain pattern 150A of the first device 100A, and the second conductivity-type epitaxial pattern 150E2′ may be formed together in the process of forming the second source/drain pattern 150B of the first device 100A. As described above, the width of the recess of second device 100B2 may be larger than the width of the recess of first device 100A, such that the first conductivity-type epitaxial pattern 150E1′ and the second conductivity-type epitaxial pattern 150E2′ may have heights lower than those of the first and second source/drain patterns 150A and 150B of the first device 100A, respectively.

In an example embodiment, the first conductivity-type epitaxial pattern 150E1′ may include a first epitaxial layer 150A1 and a second epitaxial layer 150A2 having different compositions, and the second conductivity-type epitaxial pattern 150E2′ may include a first epitaxial layer 150B1 and a second epitaxial layer 150B2 having different compositions. For example, in the first conductivity-type epitaxial pattern 150E1′, the first and second epitaxial layers 150A1 and 150A2 may be SiGe, and the second epitaxial layer 150A2 may have a concentration of germanium higher than a concentration of germanium of the first epitaxial layer 150A1.

FIG. 7 is a cross-sectional diagram illustrating a circuit device employable in a semiconductor apparatus according to example embodiments, viewed from side.

Referring to FIG. 7, a second device 100B3 according to an example embodiment may replace the second device 100B2 in the semiconductor apparatus 200A in FIGS. 5 and 6 or may be employed together with the second device 100B2, and unless otherwise indicated, the detailed description of the second device 100B3 according to an example embodiment may be combined with the description of the second device 100B2 illustrated in FIGS. 5 and 6.

The gate structure of the second device 100B3 according to an example embodiment may be a dummy gate structure DG including polysilicon. The dummy gate structure DG may be obtained by not applying the process of forming the gate structure (see FIGS. 11E and 11F) in the second region B.

Similarly to the semiconductor stack SL of the second device 100B2 in the aforementioned example embodiment, the second device 100B3 according to an example embodiment may include a semiconductor stack SL in which semiconductor layers 121L, 122L, 125L, 131L, and 132L having different compositions are stacked, and a plurality of dummy gate structure DG extending to the semiconductor stack SL and having a width and a pitch different from those of the gate structure GS of the first device 100A.

In an example embodiment, the first conductivity-type epitaxial pattern 150E1′ and the second conductivity-type epitaxial pattern 150E2′ may be formed in order in each recess on both sides. As described above, a width of the recess of the second device 100B3 may be larger than a width of the recess of the first device 100A, such that stack heights of the first conductivity-type epitaxial pattern 150E1′ and the second conductivity-type epitaxial pattern 150E2′ may be lower than stack heights of the first and second source/drain patterns 150A and 150B of the first device 100A, respectively. Also, as in an example embodiment, the second device 100B3 may not include the isolating insulation layer 170, such that the first conductivity-type epitaxial pattern 150E1′ and the second conductivity-type epitaxial pattern 150E2′ may be in contact with each other.

The second lower contact 250B of the second device 100B3 may penetrate the substrate 101 and may be connected to the first conductivity-type epitaxial pattern 150E1′, similarly to the second lower contact 250B of the second device 100B1 according to the aforementioned example embodiment. The second lower contact 250B employed in an example embodiment may include a conductive via 230 penetrating the substrate 101 and a conductive connection portion 220 formed by selectively removing the buried sacrificial pattern. The second lower contact 250B may be formed together in the process of forming the first lower contact 250A. The second lower contact 250B and the second upper contact 260B may be connected to the first conductivity-type epitaxial pattern 150E1′ of the left recess and the second conductivity-type epitaxial patterns 150E2′ of the right recess, respectively, and may be electrically connected to other devices through the first and second interconnection structures 280 and 290.

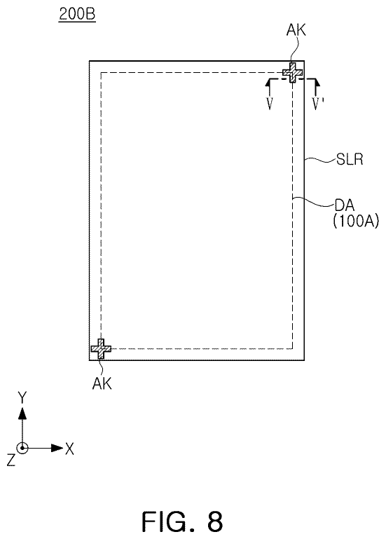

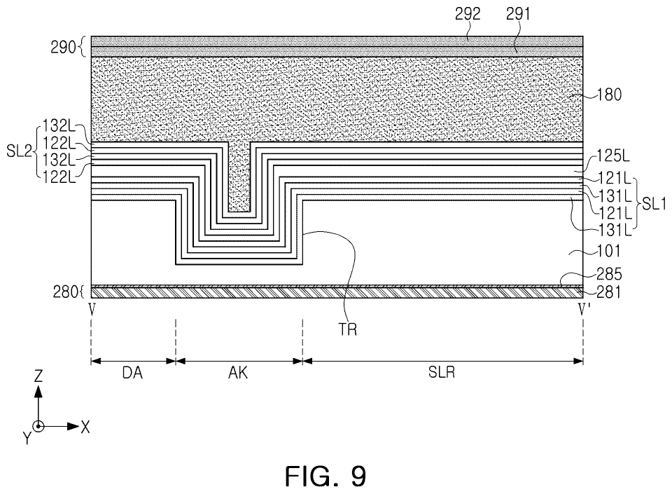

FIG. 8 is a plan diagram illustrating a semiconductor apparatus according to example embodiments. FIG. 9 is a cross-sectional diagram illustrating a semiconductor apparatus taken along line V-V′ of FIG. 8.

Referring to FIG. 8, a semiconductor apparatus 200B according to an example embodiment may include a main region DA in which first devices 100A are formed and a scribe lane region SLR disposed around the main region DA. Also, the semiconductor apparatus 200B may include an align key AK disposed in a peripheral region thereof. In the semiconductor apparatus 200B according to an example embodiment, the semiconductor stack SL to form a channel structure (CS in FIG. 2A) may also be disposed on the scribe lane region SLR and/or the align key AK.

FIG. 9 illustrates a cross section structure of the align key and the remaining scribe lane region from the edge of the main region. Since the semiconductor stack is formed throughout the substrate, the semiconductor stack may also be disposed on the align key and remaining scribe lane region. The align key employed in an example embodiment may include a trench structure, and the semiconductor stack may be formed along an internal surface of the trench.

The semiconductor stack SL may include semiconductor layers 121L, 122L, 125L, 131L, and 132L including different concentrations of germanium. In an example embodiment, the second lower semiconductor layers 131L may include silicon germanium substantially the same as that of the first semiconductor patterns 131 included in the lower channel structure. Accordingly, hole mobility may be improved in the lower channel structure. The second lower semiconductor layer 131L employed in an example embodiment may have an upper surface which may be a (110) crystal plane, similarly to the first semiconductor patterns 131. Also, the second upper semiconductor layers 132L may include substantially the same silicon as that of the second semiconductor patterns 132 included in the upper channel structure. As described above, the second lower semiconductor layers 131L may include germanium in a first concentration substantially similar to that of the first semiconductor patterns 131. For example, the second lower semiconductor layers 131L may include a concentration of germanium ranging from 4 atom % to 7 atom %. Each of the first lower semiconductor layers 121L and the first upper semiconductor layers 122L may include silicon germanium including germanium of a second concentration rather than the first concentration. For example, second concentration may range from 10 atom % to 20 atom %. In an example embodiment, the first lower semiconductor layers 121L may have a concentration of germanium greater than the concentration of germanium of each of the first upper semiconductor layers 122L. Also, the intermediate semiconductor layer 125L may include silicon germanium having germanium of a third concentration rather than the second concentration of each of the first lower semiconductor layers 121L and the first upper semiconductor layers 122L. For example, the third concentration may range from 30 atom % to 45 atom %.

Hereinafter, the method of manufacturing a semiconductor apparatus according to an example embodiment may be described.

FIGS. 10A to 10H are cross-sectional diagrams illustrating a portion of processes of a method of manufacturing a semiconductor apparatus according to example embodiments. The manufacturing method according to an example embodiment may be a method of manufacturing the semiconductor apparatus 200 illustrated in FIGS. 1 to 3B, and each cross section may correspond to the drawings in FIGS. 2A and 3A.

FIGS. 10A to 10H are cross-sectional diagrams illustrating a portion of processes of the method of manufacturing a semiconductor apparatus according to an example embodiment, illustrating main processes of forming first and second source/drain patterns. FIG. 11A to FIG. FIG. 11G are cross-sectional diagrams illustrating the other portion of processes of the method of manufacturing a semiconductor apparatus according to an example embodiment, illustrating main processes of forming gate structures and a contact structure.

Referring to FIG. 10A, a semiconductor stack SL may be formed on an upper surface of the substrate 101, that is, first and second regions A and B.

The substrate 101 may include silicon (Si), germanium (Ge), or silicon germanium (SiGe). The substrate 101 may include a bulk wafer, an epitaxial layer, or a silicon on insulator (SOI) layer. The upper surface of the substrate 101 employed in an example embodiment may be a (110) crystal plane.

The semiconductor stack SL may be formed by alternately stacking semiconductor layers 121L, 122L, 125L, 131L, and 132L having different compositions on the substrate 101. The semiconductor layers may include an intermediate semiconductor layer 125L, a lower stack SL1 including first sacrificial layers 121L (also referred to as “first lower semiconductor layer”) and first semiconductor layers 131L (also referred to as “second lower semiconductor layer”) alternately stacked under a lower surface of the intermediate semiconductor layer 125L, and an upper stack SL2 including second sacrificial layers 122L (also referred to as “first upper semiconductor layer”) and second semiconductor layers 132L (also referred to as “second upper semiconductor layer”) alternately stacked on an upper surface of the intermediate semiconductor layer 125L.

In an example embodiment, the second lower semiconductor layers 131L may include silicon germanium having a first concentration of germanium, and the second upper semiconductor layers 132L may include silicon. For example, the first concentration may range from 4 atom % to 7 atom %. Each of the first lower semiconductor layers 121L and the first upper semiconductor layers 122L may include silicon germanium including germanium of a second concentration rather than the first concentration. For example, the second concentration may range from 10 atom % to 20 atom %. In an example embodiment, the first lower semiconductor layers 121L may have a concentration of germanium greater than the concentration of germanium of each of the first upper semiconductor layers 122L. Also, the intermediate semiconductor layer 125L may include silicon germanium having germanium of a third concentration rather than the second concentration of each of the first lower semiconductor layers 121L and the first upper semiconductor layers 122L. For example, the third concentration may range from 30 atom % to 45 atom %. In some example embodiments, a thickness t1 of the intermediate semiconductor layer 125L may be greater than a thickness of each of the first and second lower semiconductor layers 121L, 131L and the first and second upper semiconductor layers 122L, 132L.

Thereafter, referring to FIG. 10B, a fin-type structure FS extending in the first direction may be formed by etching the semiconductor stack SL on the first region A, and desired impurity regions W1 and W2 may be formed in the semiconductor stack SL on the second region B.

The process of forming the fin-type structure FS may be selectively performed only in the first region A. To this end, during the process of forming the fin-type structure, the second region B may be covered with a mask (not illustrated). In the first region A, the fin-type structure FS may extend in the first direction (e.g., X-direction) on the substrate 101 and a plurality of the fin-type structures FS may be formed and arranged in the second direction (e.g., Y-direction).

Thereafter, in the second region B, first and second conductivity-type impurity regions W1 and W2 may be formed in the semiconductor stack SL to form a circuit device using an ion implantation process. The ion implantation process may be selectively performed only in the second region B. During the ion implantation process, the first region A may be covered with a mask (not illustrated). Similarly to the second device 100B illustrated in FIG. 1, in a planar view, the first conductivity-type impurity region W1 may be formed in a portion region of the semiconductor stack SL of the second region B, and the second conductivity-type impurity region W2 may be formed by counter-doping in the first conductivity-type impurity region W1.

Thereafter, referring to FIG. 10C, a plurality of dummy gate structures DG may be formed in the first and second regions A and B.

The plurality of dummy gate structures DG may extend in the second direction (e.g., Y-direction) and may be arranged in the first direction (e.g., X-direction). In an example embodiment, the plurality of dummy gate structures DG may be arranged differently with a first pitch and a first width in the first region A, and with a second pitch and a second width in the second region B. In some example embodiments, the first pitch and the second pitch may be the same, but an example embodiment thereof is not limited thereto.

The plurality of dummy gate structures DG in the first region A may be formed to intersect the fin-type structure FS (see FIG. 1), and the plurality of dummy gate structures DG in the second region B may be formed on a flat surface of the semiconductor stack SL.

In this process, gate spacers 141 may be formed on both sides of the dummy gate structures DG along with the dummy gate structures DG. The dummy gate structures DG may be provided as a sacrificial structure providing a space to form gate structures GS to be formed in respective subsequent processes. The dummy gate structures DG may include dummy material layers 245 and mask pattern layers 247. The dummy material layers 245 may be patterned using the mask pattern layer 247. The dummy material layers 245 may be an insulating layer and a conductive layer, respectively, and in some example embodiments, the dummy material layers 245 may include polysilicon. The mask pattern layer 247 may include silicon oxide and/or silicon nitride. However, an example embodiment thereof is not limited thereto, and the dummy material layers 245 may include a plurality of different material layers. For example, the dummy material layers 245 may include an additional insulating film, such as silicon oxide, below the polysilicon.

The gate spacers 141 may be formed on both sidewalls of the dummy gate structures DG. The gate spacers 141 may be formed by forming a film having a uniform thickness along an upper surface and a side surface of the substrate 101 on which dummy gate structures DG are formed, and performing anisotropically etching. The gate spacers 141 may be formed of a low dielectric constant material, and may include, for example, at least one of SiO, SiN, SiCN, SiOC, SiON, and SiOCN.

Thereafter, referring to FIG. 10D, a first recess RS1 may be formed by removing portions of the fin-type structure FS between the dummy gate structures DG in the first region A, and a second recess RS2 may be formed by removing some of portions of the semiconductor stack SL between the dummy gate structures DG in the second region B.

The processes of forming the first and second recess RS1 and RS2 may be performed in sequence. The process of forming the first recess RS1 may be selectively performed only on the first region A, and during this process, the second region B may be covered with a mask (not illustrated).

This process may include removing exposed regions of the fin-type structure FS using the dummy gate structures DG and the gate spacers 141 as a mask. Through this process, the first and second semiconductor patterns 131 and 132 may have the desired channel length in the first direction (e.g., X-direction). Side portions of the first semiconductor patterns 131 exposed by the first recess RS1 may be provided as a region for forming the first source/drain pattern, and side portions of the second semiconductor patterns 132 exposed by the first recess RS1 may be provided as a region for forming the second source/drain pattern. Also, in an example embodiment, the first recess RS1 may be formed to a sufficient depth in the substrate 101. The first recess RS1 may provide the region in which a buried sacrificial pattern (220P in FIG. 10F) for the lower contact structure is formed.

Thereafter, in the second region B, second recesses RS2 may be formed in the semiconductor stack SL. The process of forming the second recesses RS2 may be selectively performed only on the second region B, and during this process, the first region A may be covered with a mask (not illustrated).

In an example embodiment, the second recess RS2 may be formed to have a depth lower than a depth of the first recess RS1. For example, the second recess RS2 may be formed to extend from the upper stack SL2 to a portion region of the intermediate sacrificial layer 125L. This process may include removing exposed regions of the semiconductor stack SL using the dummy gate structures DG and the gate spacers 141 as a mask. The second recess RS2 may provide a space for the first and second conductivity-type epitaxial patterns.

Thereafter, referring to FIG. 10E, a dielectric pattern 191P may be formed in the first recess RS1, and a first blocking insulating layer 310 may be formed across the first and second regions A and B.

First, a first gap-fill insulating layer 191 may be formed between the dummy gate structures DG such that the first and second recesses RS1 and RS2 may be filled. The process of forming the first gap-fill insulating layer 191 may include depositing an insulating material to fill the spaces between the dummy gate structures DG and performing a planarization process such as chemical mechanical polishing (CMP). Thereafter, the dielectric pattern 191P having the desired height may be formed by selectively applying an etch-back process to the first gap-fill insulating layer 191 only in the first region A. The dielectric pattern 191P may define the region in which the buried sacrificial pattern (220P in FIG. 10F) is formed.

Thereafter, the first blocking insulating layer 310 may be formed conformally across the first and second regions A and B. The first blocking insulating layer 310 may be formed along an upper surface and a side surface of the dummy gate structures DG and the regions between the dummy gate structures DG. Also, the first blocking insulating layer 310 may also be formed on the dielectric pattern 191P. For example, the first blocking insulating layer 310 may include silicon nitride (SiN), silicon oxynitride (SiON), or silicon carbonitride (SiCN).

Thereafter, referring to FIG. 10F, the first blocking insulating layer 310 may be selectively removed to expose an upper surface of the dielectric pattern 191P, the dielectric pattern 191P may be removed, and a buried sacrificial pattern 220P may be formed in the region in which the dielectric pattern 191P is removed.

The process of selectively removing the first blocking insulating layer 310 may include anisotropic etching, such as dry etching. Portions on upper surfaces of the dielectric pattern 191P and the dummy gate structure DG of the first blocking insulating layer 310 disposed on the first region A may be selectively removed, and the first blocking insulating layer 310 disposed on the second region B may be removed entirely.

Thereafter, dielectric pattern 191P may be removed from the first recess RS1′, and the buried sacrificial pattern 220P may be formed in the region in which the dielectric pattern 191P is removed. The buried sacrificial pattern 220P may include silicon germanium. A concentration of germanium in the buried sacrificial pattern 220P may be at least higher than a concentration of germanium in the first sacrificial layer 121L. During the epitaxial growth process for the buried sacrificial pattern 220P, epitaxial layer growth in unintended regions may be prevented by the first blocking insulating layer 310P.

Thereafter, referring to FIG. 10G, the first blocking insulating layer 310P may be removed, a second blocking insulating layer 320P may be formed such that the first semiconductor patterns 131 may be opened, and the first source/drain patterns 150A may be formed in the first recess RS1′. In the process of forming the first source/drain pattern 150A, the first conductivity-type epitaxial pattern 150E1 may be formed in the open second recess RS2′ of the second region B.

After the first blocking insulating layer 310P is removed, similarly to processes described with reference to FIGS. 10E and 10F, the second blocking insulating layer 320P may be formed. First, a second gap-fill insulating layer (not illustrated) may be formed between the dummy gate structures DG in the first region A, and thereafter, by applying an etch-back process to the second gap-fill insulating layer (not illustrated) in first recesses RS1′, a dielectric pattern (not illustrated) defining the region in which the first source/drain patterns 150A is formed may be formed. Thereafter, the second blocking insulating layer 320P may be conformally formed across the first and second regions A and B, the dielectric pattern (not illustrated) may be opened by applying anisotropic etching, the dielectric pattern (not illustrated) may be removed, and side surfaces of the first semiconductor patterns 131 and the first sacrificial pattern 121 may be opened. Thereafter, the desired first source/drain patterns 150A may be formed by growing an epitaxial layer from side surfaces of the first semiconductor patterns 131 and the first sacrificial pattern 121. During the epitaxial growth process, epitaxial layer growth may be prevented in the portion in which the second blocking insulating layer 320P is formed.

In this process, by selectively opening a portion of the second recess RS2′ in the second region, the first conductivity-type epitaxial pattern 150E1 may be formed simultaneously with the process of forming the first source/drain patterns 150A. Even when the first source/drain patterns 150A and the first conductivity-type epitaxial pattern 150E1 are disposed on different levels, the patterns may be formed by the same epitaxial growth process.

The first conductivity-type epitaxial pattern 150E1 may be grown from side surfaces of the first upper semiconductor layers 122L and the second upper semiconductor layers 132L opened by the second recess RS2′. The first source/drain patterns 150A and the first conductivity-type epitaxial pattern 150E1 may include the same conductivity-type semiconductor material.

Thereafter, referring to FIG. 10H, the second blocking insulating layer 320P may be removed, an isolating insulation layer 170 may be formed, and a second gap-fill insulating layer 192 may be formed in the second region B such that other second recesses RS2″ are opened. Thereafter, the second source/drain patterns 150B may be formed in the first recess RS1″, and the second conductivity-type epitaxial patterns 150E2 may be formed in the open second recess RS2″.

After the second blocking insulating layer 320P and the first gap-fill insulating layer 191 are removed, by depositing insulating material in the first and second regions A and B, a second gap-fill insulating layer 192 may be formed between the dummy gate structures DG, and the second gap-fill insulating layer 192 may be selectively removed such that the first and second recess RS1″ and RS2″ are reopened. Thereafter, an isolating insulation layer 170 covering the first source/drain patterns 150A may be formed in the first region A, second source/drain patterns 150B may be formed in the first recess RS1″, and second conductivity-type epitaxial patterns 150E2 may be formed in the second recess RS2″. The second conductivity-type epitaxial patterns 150E2 may be formed simultaneously with the process of forming the second source/drain patterns 150B in the first recess RS1″. The second source/drain patterns 150B may be grown from side surfaces of the second semiconductor patterns 132 and the second sacrificial pattern 122 opened by the first recess RS1″, and the second conductivity-type epitaxial pattern 150E2 may be grown from side surfaces of the first upper semiconductor layers 122L and the second upper semiconductor layers 132L opened by the second recess RS2″. As such, the second source/drain patterns 150B and the second conductivity-type epitaxial pattern 150E2 may be formed by the same epitaxial growth process and may include the same conductivity-type semiconductor material.

FIGS. 11A to 11G are cross-sectional diagrams illustrating the other portion processes of a method of manufacturing a semiconductor apparatus according to example embodiments.

Referring to FIG. 11A, a process of partially removing the dummy gate structure DG may be performed. In the example illustrated in FIG. 10H, the interlayer insulating layer 180 may be formed to fill the space between the dummy gate structures DG, and a CMP process may be performed to remove the mask pattern layer 247 (e.g., up to the PL line). After this process, the dummy material layer 245 may be exposed in the dummy gate structure DG.

Thereafter, referring to FIG. 11B, the dummy material layer 245 may be removed from the first region A, and the intermediate sacrificial layer 125L may be removed by applying a selective etching process through the first space DH1 in the first region A. Accordingly, the first gap O1 from which the intermediate sacrificial layer 125L is removed may be formed.

Thereafter, referring to FIG. 11C, in the first region A, an insulating isolation pattern 160 may be formed by filling the first gap O1 with an insulating material. The insulating isolation pattern 160 may include silicon nitride (SiN), silicon oxynitride (SiON), or silicon carbonitride (SiCN).

Thereafter, referring to FIG. 11D, a gap (not illustrated) may be formed between the first semiconductor patterns 131 by selectively removing the first sacrificial pattern 121 from the first region A, and the first gate structure GS1 may be formed by depositing the first gate insulating film 142A and the first gate electrode 145A to surround the first semiconductor patterns 131 exposed by the gap (not illustrated).

Thereafter, referring to FIG. 11E, a second gap O2 between the second semiconductor patterns 132 may be formed by selectively removing the second sacrificial patterns 122 from the first region A.

Before this process, a second space DH2 may be formed by removing the dummy material layer 245 from second region B. While the second sacrificial patterns 122 in first region A is removed, none of the sacrificial layers of the semiconductor stack SL may be removed from the second region B. Differently from the first region A, the semiconductor stack SL of the second region B may not be a fin-type structure, such that only an upper surface of the semiconductor stack SL, that is, the second upper semiconductor layer 132L, may be exposed by the second space DH2. Accordingly, during the process of selectively removing the sacrificial patterns from the first region A, the sacrificial layers of the semiconductor stack SL in the second region B may not be etched.

Thereafter, referring to FIG. 11F, the second gate insulating film 142B may be conformally formed in the first region A to surround the second semiconductor patterns 132 exposed through the second gap O2. Also, the second gate insulating film 142B may also be formed on inner surfaces of first and second spaces DH1 and DH2. Thereafter, the second gate electrodes 145B may be formed to fill the second gap O2 and the first and second spaces DH1 and DH2. After forming the gate capping layer 147 on the second gate electrodes 145B, by performing a CMP process, the second gate structure GS2 and GS2′ may be formed in the first and second regions A and B.

Thereafter, referring to FIG. 11G, first upper contact 260A and second upper contacts 260B1, 260B2, and 260B3 may be formed in the first and second regions A and B, and a front interconnection structure 290 may be formed. Thereafter, in the first region A, a through-hole may be formed to be connected to the buried sacrificial pattern 220P on one side, the connected buried sacrificial pattern 220P may be removed, and the through-hole may be filled with conductive material, thereby forming the first lower contact 250A. Thereafter, by forming a rear interconnection structure 280 electrically connected to the first lower contact 250A under a lower surface of the substrate 101, the semiconductor apparatus 200 illustrated in FIGS. 2A and 3A may be manufactured.

According to the aforementioned example embodiments, to improve carrier mobility, the channel layer may be formed with silicon germanium, and to introduce the structure, the concentration of germanium in various sacrificial layers may be appropriately changed. Also, circuit devices such as passive devices and a peripheral region may include a semiconductor stack having the changed structure.

While example embodiments have been illustrated and described above, it will be configured as apparent to those skilled in the art that modifications and variations could be made without departing from the scope of the present disclosure as defined by the appended claims.

What is claimed is:

1. A semiconductor apparatus, comprising:
a substrate including a first region and a second region;
a semiconductor device on the first region of the substrate; and
a semiconductor stack on the second region of the substrate,
wherein the semiconductor device includes
a channel structure including an insulating isolation pattern, first semiconductor patterns under a lower surface of the insulating isolation pattern and being stacked and spaced apart from each other in a vertical direction, and second semiconductor patterns stacked and spaced apart from each other in the vertical direction on an upper surface of the insulating isolation pattern,
first source/drain patterns on both sides in a first direction of the channel structure and connected to both sides of the first semiconductor patterns, respectively,
second source/drain patterns on the both sides of the channel structure and connected to both sides of the second semiconductor patterns, respectively,
a first gate structure extending in a second direction intersecting the first direction and surrounding the first semiconductor patterns, and
a second gate structure extending in the second direction and surrounding the second semiconductor patterns,
wherein the semiconductor stack includes
an intermediate semiconductor layer at a level corresponding to a level of the insulating isolation pattern,
first lower semiconductor layers and second lower semiconductor layers alternately stacked under a lower surface of the intermediate semiconductor layer, and
first upper semiconductor layers and second upper semiconductor layers alternately stacked on an upper surface of the intermediate semiconductor layer,
wherein the first semiconductor patterns and the second lower semiconductor layers include a first semiconductor material, and the second semiconductor patterns and the second upper semiconductor layers include a second semiconductor material,
wherein one of the first semiconductor material and the second semiconductor material includes silicon and an other of the first semiconductor material and the second semiconductor material includes silicon germanium including germanium in a first concentration, and
wherein the first lower semiconductor layers and the first upper semiconductor layers include silicon germanium including germanium in a second concentration,
the second concentration is higher than the first concentration,
the intermediate semiconductor layer includes silicon germanium in a third concentration, and
the third concentration is higher than the second concentration.

2. The semiconductor apparatus of claim 1, wherein
the first semiconductor material includes silicon germanium including germanium of the first concentration, and
the second semiconductor material includes silicon.

3. The semiconductor apparatus of claim 2, wherein
the first source/drain patterns include silicon germanium, and
the second source/drain patterns include silicon.

4. The semiconductor apparatus of claim 2, wherein
an upper surface of the first semiconductor patterns is a (110) crystal plane, and
an upper surface of the second semiconductor patterns is a (110) crystal plane.

5. The semiconductor apparatus of claim 1, wherein
the first concentration is in a range of 4 atom % to 7 atom %,
the second concentration is in a range of 10 atom % to 20 atom %, and
the third concentration is in a range of 30 atom % to 45 atom %.

6. The semiconductor apparatus of claim 1, wherein
the first lower semiconductor layers have a concentration of germanium greater than a concentration of germanium of the first upper semiconductor layers.

7. The semiconductor apparatus of claim 1, further comprising:
a circuit device including the semiconductor stack as a body thereof on the second region of the substrate.

8. The semiconductor apparatus of claim 7, wherein the semiconductor stack includes at least one of a first conductivity-type impurity region and a second conductivity-type impurity region.

9. The semiconductor apparatus of claim 7, wherein the second region further includes a plurality of gate structures extending on the semiconductor stack in the second direction.

10. The semiconductor apparatus of claim 9, wherein the plurality of gate structures include inactive gate structures.

11. The semiconductor apparatus of claim 9, wherein the plurality of gate structures include polycrystalline silicon.

12. The semiconductor apparatus of claim 9,
wherein the semiconductor stack includes a first recess and a second recess between the plurality of gate structures, and
wherein the circuit device includes a first conductivity-type epitaxial pattern and a second conductivity-type epitaxial pattern in the first recess and the second recess, respectively, and the first conductivity-type epitaxial pattern and the second conductivity-type epitaxial pattern are connected to the semiconductor stack.

13. The semiconductor apparatus of claim 12,
wherein a material in the first conductivity-type epitaxial pattern is a same material as a material in the first source/drain patterns, and
wherein a material in the second conductivity-type epitaxial pattern is a same material as a material in the second source/drain patterns.

14. The semiconductor apparatus of claim 1, wherein the second region is a peripheral region of the substrate.

15. The semiconductor apparatus of claim 1, wherein the second region includes a trench structure, and the semiconductor stack is formed along an internal surface of the trench structure.

16. A semiconductor apparatus, comprising:
a substrate including a first region and a second region;
a first device on the first region of the substrate; and
a second device on the second region of the substrate,
wherein the first device includes
a channel structure including an insulating isolation pattern, first semiconductor patterns under a lower surface of the insulating isolation pattern and being stacked and spaced apart from each other in a vertical direction, and second semiconductor patterns stacked and spaced apart from each other in the vertical direction on an upper surface of the insulating isolation pattern, the first semiconductor patterns and the second semiconductor patterns including silicon germanium and silicon, respectively,
a pair of first source/drain patterns on both sides in a first direction of the channel structure and connected to both sides of the first semiconductor patterns, respectively,
a pair of second source/drain patterns on the both sides of the channel structure and connected to both sides of the second semiconductor patterns, respectively, and
a gate structure extending in a second direction, the second direction intersecting the first direction, the gate structure surrounding the first semiconductor patterns and the second semiconductor patterns,
wherein the second device includes a semiconductor stack at a level corresponding to a level of the channel structure, and
the semiconductor stack includes an intermediate semiconductor layer, first lower semiconductor layers and second lower semiconductor layers alternately stacked under a lower surface of the intermediate semiconductor layer, and first upper semiconductor layers and second upper semiconductor layers alternately stacked on an upper surface of the intermediate semiconductor layer, and
wherein the intermediate semiconductor layer, the first lower semiconductor layers, the second lower semiconductor layers, and the first upper semiconductor layers include silicon germanium,
the second upper semiconductor layers include silicon, and
the first semiconductor patterns and the second lower semiconductor layers have a same concentration of germanium.

17. The semiconductor apparatus of claim 16, wherein
each of the first semiconductor patterns and the second lower semiconductor layers include silicon germanium having an upper surface of a (110) crystal plane and a concentration of germanium in a range of 4 atom % to 7 atom %.

18. The semiconductor apparatus of claim 17, wherein
each of the first lower semiconductor layers and the first upper semiconductor layers have a concentration of germanium in a range of 10 atom % to 20 atom %, and
the intermediate semiconductor layer has a concentration of germanium in a range of 30 atom % to 45 atom %.

19. The semiconductor apparatus of claim 16, further comprising:
a plurality of gate structures extending to the semiconductor stack and extending in the second direction in the second region; and
a plurality of conductivity-type epitaxial patterns in a plurality of recesses formed in regions between the plurality of gate structures of the semiconductor stack, respectively, and
wherein a material of each of the plurality of conductivity-type epitaxial patterns is a same material as a material of one of the first source/drain patterns and the second source/drain patterns.

20. A semiconductor apparatus, comprising:
a substrate including a first region and a second region, the second region being peripheral to the first region;
a semiconductor device on the first region of the substrate; and
a semiconductor stack on the second region of the substrate,
wherein the semiconductor device includes an insulating isolation pattern, first semiconductor patterns under a lower surface of the insulating isolation pattern and stacked and spaced apart from each other in a vertical direction, and second semiconductor patterns stacked and spaced apart from each other in the vertical direction on an upper surface of the insulating isolation pattern, the first semiconductor patterns and the second semiconductor patterns including silicon germanium and silicon, respectively,
wherein the semiconductor stack includes an intermediate semiconductor layer at a level corresponding to a level of the insulating isolation pattern, first lower semiconductor layers and a second lower semiconductor layer alternately stacked under a lower surface of the intermediate semiconductor layer, and first upper semiconductor layers and second upper semiconductor layers alternately stacked on an upper surface of the intermediate semiconductor layer,
wherein the intermediate semiconductor layer, the first lower semiconductor layers, the second lower semiconductor layers, and the first upper semiconductor layers include silicon germanium, and the second upper semiconductor layers include silicon, and
wherein the first semiconductor patterns and the second lower semiconductor layers includes germanium in a first concentration, the first lower semiconductor layers and the first upper semiconductor layers includes germanium in a second concentration, the second concentration is higher than the first concentration, the intermediate semiconductor layer includes germanium in a third concentration, and the third concentration is higher than the second concentration.
